(19) United States
(12) Patent Application Publication
(10) Pub. No.: US 2022/0101108 A1
(43) Pub. Date: Mar. 31, 2022

(54) MEMORY-MAPPED NEURAL NETWORK ACCELERATOR FOR DEPLOYABLE INFERENCE SYSTEMS

(71) Applicant: INTERNATIONAL BUSINESS MACHINES CORPORATION, Armonk, NY (US)

(72) Inventors: Filipp Akopyan, New Windsor, NY (US); John Vernon Arthur, Mountain View, CA (US); Andrew Stephen Cassidy, San Jose, CA (US); Michael Vincent DeBole, Poughkeepsie, NY (US); Carmelo Di Nolfo, San Jose, CA (US); Myron D. Flickner, San Jose, CA (US); Jeffrey A. Kusnitz, Campbell, CA (US); Dharmendra S. Modha, San Jose, CA (US); Carlos Ortega Otero, San Jose, CA (US); Jun Sawada, Austin, TX (US); Benjamin Gordon Shaw, San Jose, CA (US); Brian Seisho Taba, Cupertino, CA (US)

(21) Appl. No.: 17/039,559

(22) Filed: Sep. 30, 2020

(51) Int. Cl. G06N 3/063; G06N 3/04; G11C 11/54

(52) U.S. Cl. CPC G06N 3/063; G11C 11/54; G06N 3/0454

(57) ABSTRACT

A neural network processor system is provided comprising at least one neural network processing core, an activation memory, an instruction memory, and at least one control register, the neural network processing core adapted to implement neural network computation, control and communication primitives. A memory map is included which comprises regions corresponding to each of the activation memory, instruction memory, and at least one control register. Additionally, an interface operatively connected to the neural network processor system is included, with the interface being adapted to communicate with a host and to expose the memory map.

### BACKGROUND

Embodiments of the present disclosure relate to systems for neural inference, and more specifically, to memory-mapped neural network accelerators for deployable inference systems.

### BRIEF SUMMARY

According to embodiments of the present disclosure, methods of and computer program products for a system comprising: a neural network processor system, comprising at least one neural network processing core, an activation memory, an instruction memory, and at least one control register, the neural network processing core adapted to implement neural network computation, control and communication primitives; a memory map comprising regions corresponding to each of the activation memory, instruction memory, and at least one control register, an interface operatively connected to the neural network processor system, the interface being adapted to communicate with a host and to expose the memory map.

According to embodiments of the present disclosure, the neural network processor is configured to receive a neural network description via the interface, to receive input data via the interface, and to provide output data via the interface. In some embodiments, the neural network processor system exposes an API via the interface, the API comprising methods for receiving the neural network description via the interface, receiving input data via the interface, and providing output data via the interface. In some embodiments, the interface comprises an AXI, PCIe, USB, Ethernet, or Firewire interface.

In some embodiments, the system further comprises a redundant neural network processing core, the redundant neural network processing core configured to compute a neural network model in parallel to the neural network processing core. In some embodiments, the neural network processor system is configured to provide redundant computation of a neural network model, and/or is configured to provide at least one of hardware, software, and model-level redundancy. In some embodiments, the neural network processor system comprises programmable firmware, the programmable firmware configurable to process the input data and output data. In some embodiments, said processing comprises buffering. In some embodiments, the neural network processor system comprises non-volatile memory. In some embodiments, the neural network processor system is configured to store configuration or operating parameters, or program state. In some embodiments, the interface is configured for real time or faster than real time operation. In some embodiments, the interface is communicatively coupled to at least one sensor or camera. In some embodiments the system comprises a plurality of the systems as described above, interconnected by a network. In some embodiments a system is provided including a plurality of the systems as described above, and a plurality of computing nodes, interconnected by a network. In some embodiments, the system further comprises a plurality of disjoint memory maps, each corresponding to one of the plurality of the systems as described above.

In accordance with another aspect of the disclosure, a method is provided which comprises: receiving a neural network description at a neural network processor system via an interface from a host, the neural network processor system comprising at least one neural network processing core, an activation memory, an instruction memory, and at least one control register, the neural network processing core adapted to implement neural network computation, control and communication primitives, the interface operatively connected to the neural network processor system; exposing a memory map via the interface, the memory map comprising regions corresponding to each of the activation memory, instruction memory, and at least one control register; receiving input data at the neural network processor system via the interface; computing output data from the input data based on the neural network model; and providing the output data from the neural network processor system via the interface. In some embodiments, the neural network processor system receives a neural network description via the interface, receives input data via the interface, and provides output data via the interface. In some embodiments, the neural network processor system exposes an API via the interface, the API comprising methods for receiving the neural network description via the interface, receiving input data via the interface, and providing output data via the interface. In some embodiments, the interface operates at real time or faster than real time speed.

### BRIEF DESCRIPTION OF THE SEVERAL VIEWS OF THE DRAWINGS

FIG. 1 illustrates an exemplary memory-mapped (MM) system according to embodiments of the present disclosure.

FIG. 2 illustrates an exemplary message passing (MP) system according to embodiments of the present disclosure.

FIG. 3 illustrates a neural core according to embodiments of the present disclosure.

FIG. 4 illustrates an exemplary Inference Processing Unit (IPU) according to embodiments of the present disclosure.

FIG. 5 illustrates a multi-core Inference Processing Unit (IPU) according to embodiments of the present disclosure.

FIG. 6 illustrates a neural core and associated networks according to embodiments of the present disclosure.

FIG. 7 illustrates a method of integration between a host system and an IPU according to embodiments of the present disclosure.

FIGS. 8A-C illustrate exemplary methods of redundancy according to embodiments of the present disclosure.

FIG. 9 illustrates a system architecture of a memory-mapped neural inference engine according to embodiments of the present disclosure.

FIG. 10 illustrates an exemplary runtime software stack according to embodiments of the present disclosure.

FIG. 11 illustrates an exemplary sequence of execution according to embodiments of the present disclosure.

FIG. 12 illustrates an exemplary integration of neural inference device according to embodiments of the present disclosure.

FIG. 13 illustrates an exemplary integration of neural inference device according to embodiments of the present disclosure.

FIG. 14 illustrates an exemplary configuration in which a neural inference device is interconnected to a host via a PCIe bridge according to embodiments of the present disclosure.

FIG. 15 illustrates a flow chart of a method of exposing a memory map in a neural network processor system according to embodiments of the present disclosure.

FIG. 16 depicts a computing node according to embodiments of the present disclosure.

### DETAILED DESCRIPTION

Various traditional computing systems communicate between system components via a shared memory/memory mapped (MM) paradigm. In contrast, various parallel, distributed computing systems, such as neurosynaptic systems, intercommunicate via a message passing (MP) paradigm. The present disclosure provides for efficient interfaces between these two types of systems.

An artificial neuron is a mathematical function whose output is a nonlinear function of a linear combination of its inputs. Two neurons are connected if the output of one is an input to the other. A weight is a scalar value encoding the strength of the connection between the output of one neuron and the input of another neuron.

A neuron computes its output, called an activation, by applying a nonlinear activation function to a weighted sum of its inputs. A weighted sum is an intermediate result computed by multiplying each input with the corresponding weight and accumulating the products. A partial sum is a weighted sum of a subset of inputs. A weighted sum of all inputs may be computed in stages by accumulating one or more partial sums.

A neural network is a collection of one or more neurons. A neural network is often divided into groups of neurons called layers. A layer is a collection of one or more neurons that all receive input from the same layers and all send output to the same layers, and typically perform a similar function. An input layer is a layer that receives input from a source outside the neural network. An output layer is a layer that sends output to a target outside the neural network. All other layers are intermediate processing layers. A multilayer neural network is a neural network with more than one layer. A deep neural network is a multilayer neural network with many layers.

A tensor is a multidimensional array of numerical values. A tensor block is a contiguous subarray of the elements in a tensor.

Each neural network layer is associated with a parameter tensor V, weight tensor W, input data tensor X, output data tensor Y, and intermediate data tensor Z. The parameter tensor contains all of the parameters that control neuron activation functions a in the layer. The weight tensor contains all of the weights that connect inputs to the layer. The input data tensor contains all of the data that the layer consumes as input. The output data tensor contains all of the data that the layer computes as output. The intermediate data tensor contains any data that the layer produces as intermediate computations, such as partial sums.

The data tensors (input, output, and intermediate) for a layer may be 3-dimensional, where the first two dimensions may be interpreted as encoding spatial location and the third dimension as encoding different features. For example, when a data tensor represents a color image, the first two dimensions encode vertical and horizontal coordinates within the image, and the third dimension encodes the color at each location. Every element of the input data tensor X can be connected to every neuron by a separate weight, so the weight tensor W generally has 6 dimensions, concatenating the 3 dimensions of the input data tensor (input row a, input column b, input feature c) with the 3 dimensions of the output data tensor (output row i, output column j, output feature k). The intermediate data tensor Z has the same shape as the output data tensor Y. The parameter tensor V concatenates the 3 output data tensor dimensions with an additional dimension o that indexes the parameters of the activation function σ. In some embodiments, activation function σ requires no additional parameters, in which case the additional dimension is unnecessary. However, in some embodiments, activation function a requires at least one additional parameter, which appears in dimension o.

An element of a layer's output data tensor Y can be computed as in Equation 1 where the neuron activation function σ is configured by the vector of activation function parameters V[i,j,k,:], and the weighted sum Z[i,j,k] can be computed as in Equation 2.

$$\begin{matrix}Y [ i , j , k ] = σ ( V [ i , j , k , \text{:} ] ; Z [ i , j , k ] ) & Equation 1 \\ Z [ i , j , k ] = {\sum }_{a = 1}^{A} {\sum }_{b = 1}^{B} {\sum }_{c = 1}^{C} W [ i , j , k , a , b , c ] \cdot X [ a , b , c ] & Equation 2\end{matrix}$$

For simplicity of notation, the weighted sum in Equation 2 may be referred to as the output, which is equivalent to using a linear activation function Y[i,j,k]=σ(Z[i,j,k])=Z[i,j,k], with the understanding that the same statements apply without loss of generality when a different activation function is used.

In various embodiments, computation of the output data tensor as described above is decomposed into smaller problems. Each problem may then be solved on one or more neural core, or on one or more core of a conventional multicore system in parallel.

It will be apparent from the above that neural networks are parallel structures. Neurons in a given layer receive inputs, X with elements xᵢ from one or more layers or other inputs. Each neuron computes its state, y∈Y based on the inputs and weights W with elements wᵢ. In various embodiments, the weighed sum of inputs is adjusted by a bias b, and then the result is passed to a nonlinearity F(⋅). For example, a single neuron activation may be expressed as y=F(b+Σxᵢwᵢ).

Because all neurons in a given layer receive inputs from the same layers and compute their outputs independently, neuron activations can be computed in parallel. Because of this aspect of the overall neural network, performing computation in parallel distributed cores accelerates overall computation. Further, within each core vector operations can be computed in parallel. Even with recurrent inputs, for example when a layer projects back to itself, all neurons are still updated simultaneously. Effectively, the recurrent connections are delayed to align with a subsequent input to the layer.

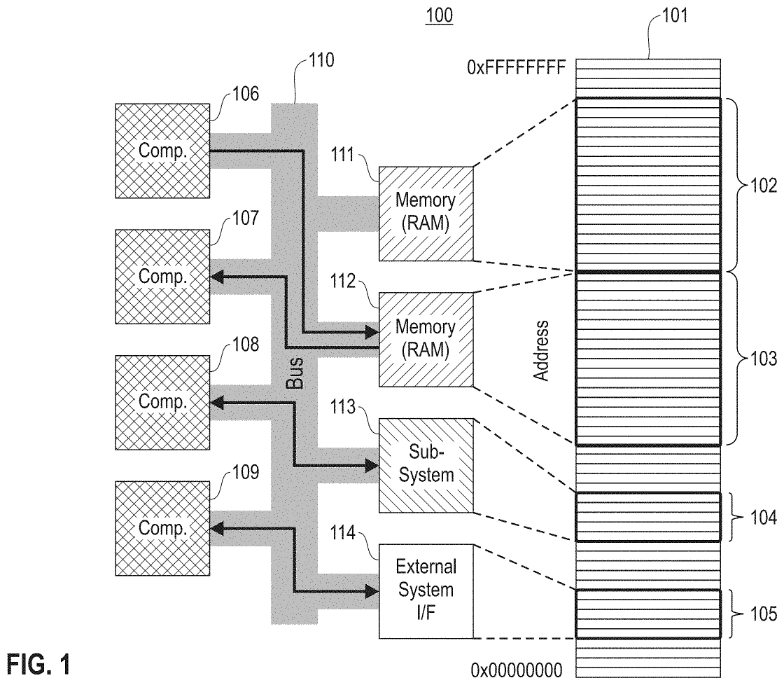

Referring to FIG. 1, an exemplary memory-mapped system 100 is illustrated. Memory map 101 is segmented and regions 102 . . . 105 are allocated to various system components. Computational cores 106 . . . 109, e.g., processor cores on one or more chips, are connected to bus 110. Each core 106 . . . 109 is connected to bus 110, and can intercommunicate through shared memory 111 . . . 112, which correspond to addressable regions of the memory map 102 . . . 103. Each core 106 . . . 109 can communicate with subsystem 113 through an addressable region 104 of the memory map 101. Similarly, each core 106 . . . 109 can communicate with an external system 114 through an addressable region 105 of the memory map 101.

Memory map (MM) addresses are in relation to the global memory map, in this example running from 0x00000000 to 0xFFFFFFFF.

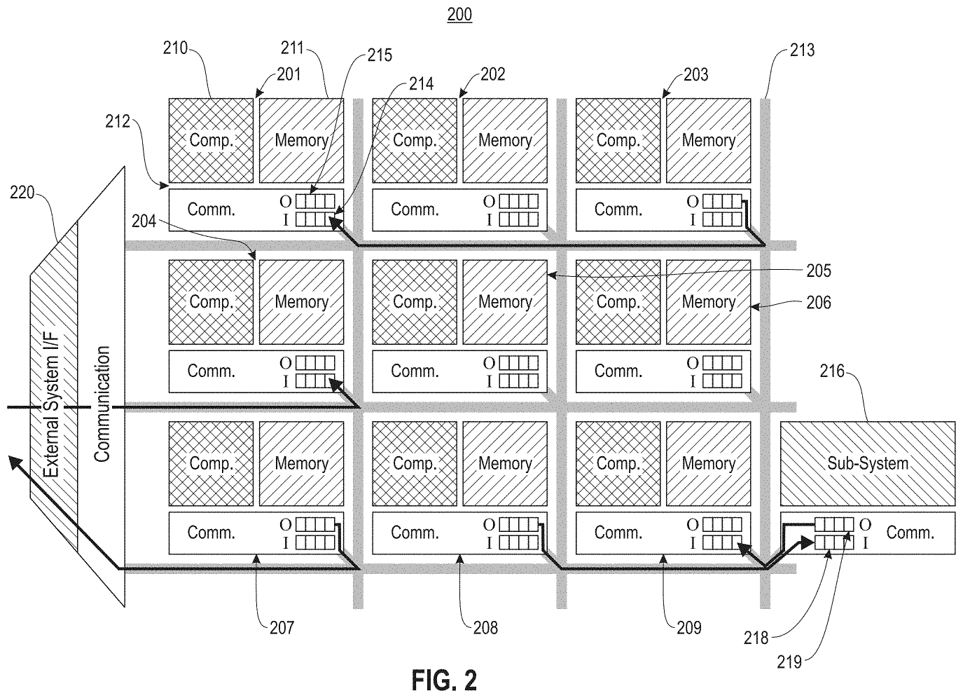

Referring to FIG. 2, an exemplary message passing (MP) system 200 is illustrated. A plurality of cores 201 . . . 209 each comprise a computational core 210, a memory 211, and communication interface 212. Each of cores 201 . . . 209 is connected by network 213. Communication interface 212 comprises an input buffer 214 and an output buffer 215 for injecting and receiving packets to/from the network 213. In this way, cores 201 . . . 209 may intercommunicate by passing messages.

Similarly, subsystem 216 may be connected to network 213 via communication interface 217 having input buffer 218 and output buffer 219. External systems may be connected to network 213 via interface 220. In this way, cores 201 . . . 209 may communicate with subsystems and external systems by passing messages.

Message-passing (MP) addresses are in relation to network addresses local to the core. For example, an individual core may be identified by its X,Y position on a chip, while the local addresses may be used for buffer or memory local to an individual core.

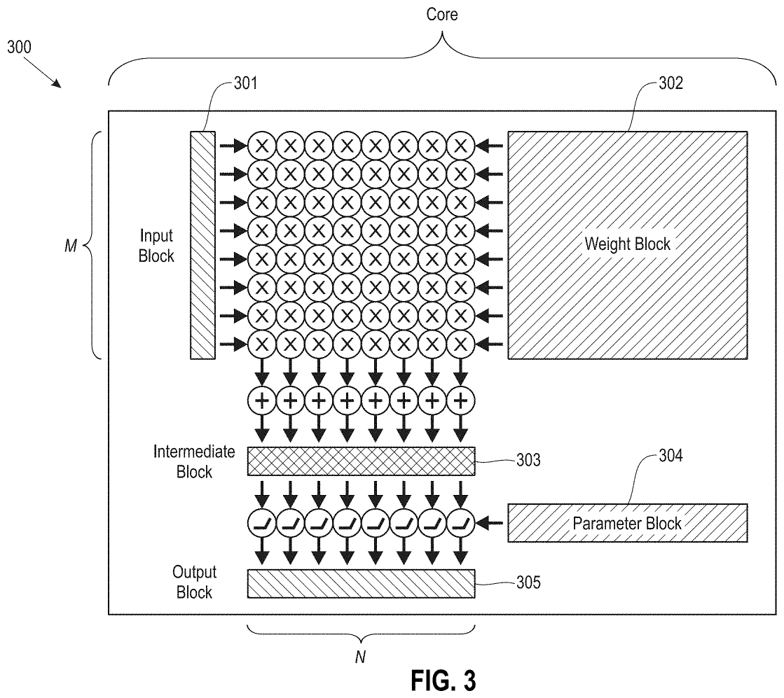

With reference now to FIG. 3, a neural core according to embodiments of the present disclosure is depicted. A neural core 300 is a tileable computational unit that computes one block of an output tensor. A neural core 300 has M inputs and N outputs. In various embodiments, M=N. To compute an output tensor block, a neural core multiplies an M×1 input tensor block 301 with an M×N weight tensor block 302 and accumulates the products into weighted sums that are stored in a 1×N intermediate tensor block 303. A O×N parameter tensor block contains the O parameters that specify each of the N neuron activation functions that are applied to the intermediate tensor block 303 to produce a 1×N output tensor block 305.

Multiple neural cores may be tiled in a neural core array. In some embodiments, the array is 2-dimensional.

A neural network model is a set of constants that collectively specify the entire computation performed by a neural network, including the graph of connections between neurons as well as the weights and activation function parameters for every neuron. Training is the process of modifying the neural network model to perform a desired function. Inference is the process of applying a neural network to an input to produce an output, without modifying the neural network model.

An inference processing unit is a category of processors that perform neural network inference. A neural inference chip is a specific physical instance of an inference processing unit.

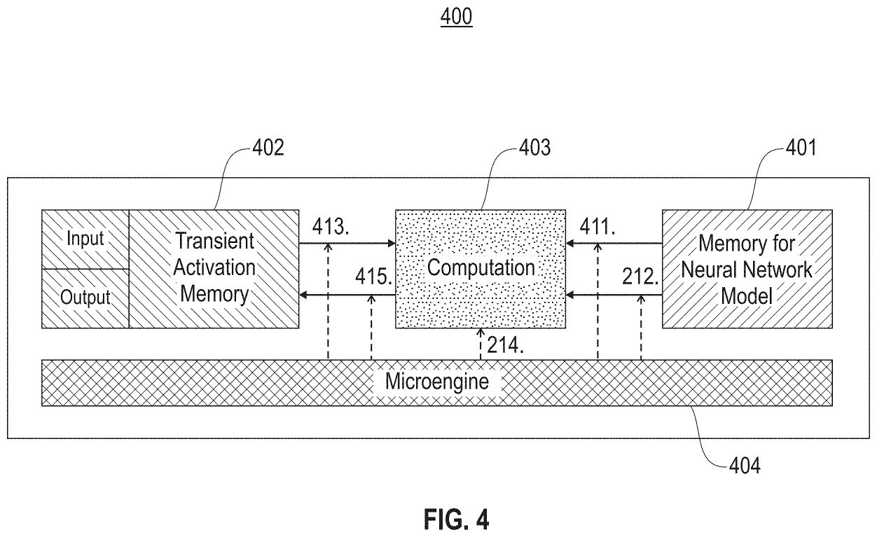

Referring to FIG. 4, an exemplary Inference Processing Unit (IPU) is illustrated according to embodiments of the present disclosure. IPU 400 includes a memory 401 for the neural network model. As described above, the neural network model may include the synapse weights for a neural network to be computed. IPU 400 includes an activation memory 402, which may be transient. Activation memory 402 may be divided into input and output regions, and stores neuron activations for processing. IPU 400 includes a neural computation unit 403, which is loaded with a neural network model from model memory 401. Input activations are provided from activation memory 402 in advance of each computation step. Outputs from neural computation unit 403 are written back to activation memory 402 for processing on the same or another neural computation unit.

In various embodiments a microengine 404 is included in IPU 400. In such embodiments, all operations in the IPU are directed by the microengine. As set out below, central and/or distributed microengines may be provided in various embodiments. A global microengine may be referred to as a chip microengine, while a local microengine may be referred to as a core microengine or local controller. In various embodiments a microengine comprises one or more microengines, microcontrollers, state machines, CPUs, or other controllers.

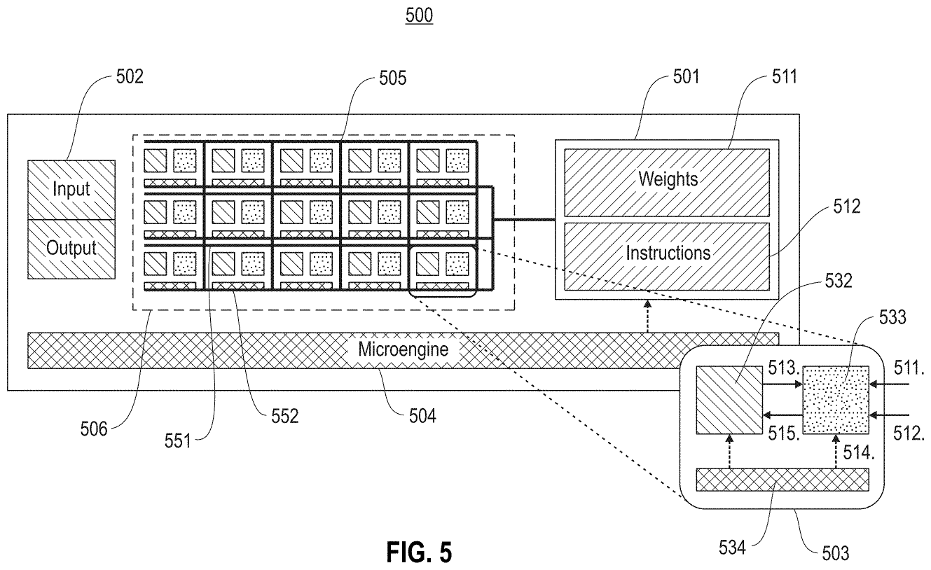

Referring to FIG. 5, a multi-core Inference Processing Unit (IPU) is illustrated according to embodiments of the present disclosure. IPU 500 includes a memory 501 for the neural network model and instructions. In some embodiments, memory 501 is divided into weight portion 511 and instruction portion 512. As described above, the neural network model may include the synapse weights for a neural network to be computed. IPU 500 includes an activation memory 502, which may be transient. Activation memory 502 may be divided into input and output regions, and stores neuron activations for processing.

IPU 500 includes an array 506 of neural cores 503. Each core 503 includes a computation unit 533, which is loaded with a neural network model from model memory 501 and is operative to perform vector computation. Each core also includes a local activation memory 532. Input activations are provided from local activation memory 532 in advance of each computation step. Outputs from computation unit 533 are written back to activation memory 532 for processing on the same or another computation unit.

IPU 500 includes one or more network-on-chip (NoC) 505. In some embodiments, a partial sum NoC 551 interconnects the cores 503 and transports partial sums among them. In some embodiments, a separate parameter distribution NoC 552 connects cores 503 to memory 501 for distributing weights and instructions to cores 503. It will be appreciated that various configurations of NoC 551 and 552 are suitable for use according to the present disclosure. For example, broadcast networks, row broadcast networks, tree networks, and switched networks may be used.

In various embodiments a global microengine 504 is included in IPU 500. In various embodiments, a local core controller 534 is included on each core 503. In such embodiments, the direction of operations is shared between the global microengine (chip microengine) and the local core controller (core microengine). In particular, at 511, compute instructions are loaded from model memory 501 to the neural computation unit 533 on each core 503 by global microengine 504. At 512, parameters (e.g., neural network/synaptic weights) are loaded from model memory 501 to the neural computation unit 533 on each core 503 by global microengine 504. At 513, neural network activation data are loaded from activation local activation memory 532 to neural computation unit 533 on each core 503 by local core controller 534. As noted above, the activations are provided to the neurons of the particular neural network defined by the model, and may originate from the same or another neural computation unit, or from outside the system. At 514, neural computation unit 533 performs the computation to generate output neuron activations as directed by local core controller 534. In particular, the computation comprises applying the input synaptic weights to the input activations. It will be appreciated that various methods are available for performing such computations, including in silico dendrites, as well as vector multiplication units. At 515, the results from computation are stored in local activation memory 532 as directed by local core controller 534. As described above, these stages may be pipelined, in order to provide efficient usage of the neural computation unit on each core. It will also be appreciated that inputs and outputs may be transferred from local activation memory 532 to global activation memory 502 according to the requirements of a given neural network.

Accordingly, the present disclosure provides for runtime control of operations in an Inference Processing Unit (IPU). In some embodiments, the microengine is centralized (single microengine). In some embodiments, the IPU computation is distributed (performed by an array of cores). In some embodiments, runtime control of operations is hierarchical—both a central microengine and distributed microengines participate.

The microengine or microengines direct the execution of all operations in the IPU. Each microengine instruction corresponds to several sub-operations (e.g., address generation, load, compute, store, etc.) In the distributed case, core microcode is run on the core microengines (e.g., 534). The core microcode includes instruction(s) to execute a full, single tensor operation. For example, a convolution between a weight tensor and a data tensor. In the context of a single core, the core microcode includes instruction(s) to execute a single tensor operation on the locally stored subset of the data tensor (and partial sums). Chip microcode is run on the chip microengine (e.g., 504). Microcode includes instructions to execute all of the tensor operations in a neural network.

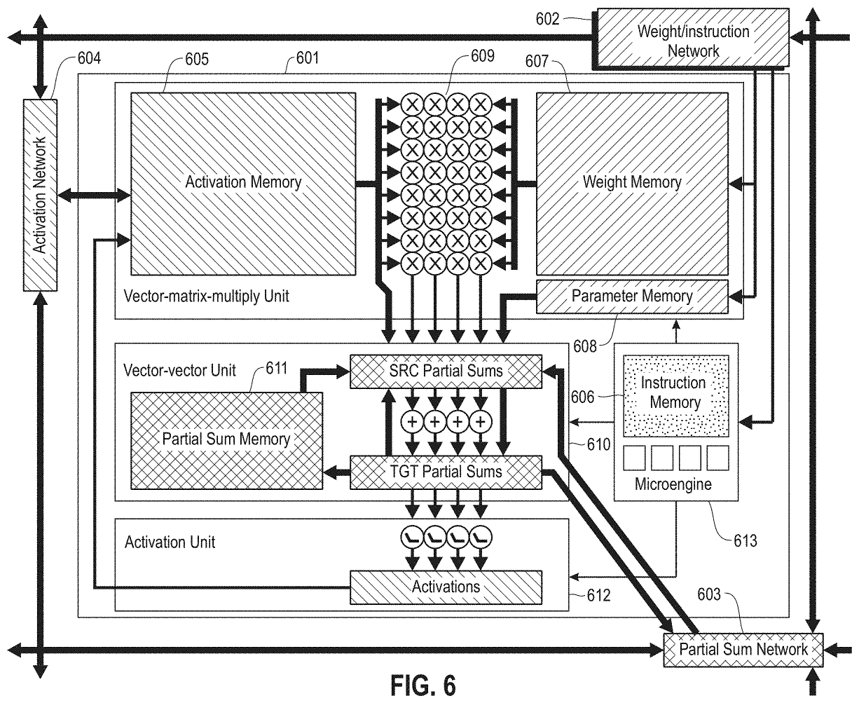

With reference now to FIG. 6, an exemplary neural core and associated networks are illustrated according to embodiments of the present disclosure. Core 601, which may be embodied as described with reference to FIG. 3 is interconnected with additional cores by networks 602 . . . 604. In this embodiments, network 602 is responsible for distributing weights and/or instructions, network 603 is responsible for distributing partial sums, and network 604 is responsible for distributing activations. However, it will be appreciated that the various embodiments of the present disclosure may combine these networks, or further separate them into multiple additional networks.

Input activations (X) are distributed core 601 from off-core via activation network 604 to activation memory 605. Layer instructions are distributed to core 601 from off-core via weight/instruction network 602 to instruction memory 606. Layer weights (W) and/or parameters are distributed to core 601 from off-core via weight/instruction network 602 to weight memory 607 and/or parameter memory 608.

The weight matrix (W) is read from weight memory 607 by Vector Matrix Multiply (VMM) unit 609. The activation vector (V) is read from activation memory 605 by Vector Matrix Multiply (VMM) unit 609. Vector Matrix Multiply (VMM) unit 609 then computes vector-matrix multiplication Z=X^{T}W and provides the result to Vector-Vector unit 610. Vector-Vector unit 610 reads additional partial sums from partial sum memory 611, and receives additional partial sums from off-core via partial sum network 603. A vector-vector operation is computed by Vector-Vector unit 610 from these source partial sums. For example, the various partial sums may in turn be summed. The resulting target partial sums are written to partial sum memory 611, sent off-core via partial sum network 603, and/or fed back for further processing by Vector-Vector unit 610.

The partial sum results from Vector-Vector unit 610, after all computation for a given layer's inputs is complete, are provided to activation unit 612 for the computation of output activations. The activation vector (Y) is written to activation memory 605. Layer activations (including the results written to activation memory) are redistributed across cores from activation memory 605 via activation network 604. Upon receipt, they are written to local activation memory to each receiving core. Upon completion of processing for a given frame, the output activations are read from activation memory 605 and sent off-core via network 604.

Accordingly, in operation, a core control microengine (e.g., 613) orchestrates the data movement and computation of the core. The microengine issues a read activation memory address operation to load an input activation block into the vector-matrix multiply unit. The microengine issues a read weight memory address operation to load a weight block into the vector-matrix multiply unit. The microengine issues the vector-matrix multiply unit a compute operation, such that vector-matrix multiply unit compute array computes a partial sum block.

The microengine issues one or more of a partial sum read/write memory address operation, vector compute operation, or partial sum communication operation in order to do one or more of the following: read partial sum data from partial sum sources; compute using partial sums arithmetic units; or write partial sum data to partial sum targets. Writing partial sum data to partial sum targets may include communicating external to the core via the partial sum network interface or sending partial sum data to the activation arithmetic unit.

The microengine issues an activation function compute operation, such that the activation function arithmetic unit computes an output activation block. The microengine issues a write activation memory address and the output activation block is written to the activation memory via the activation memory interface.

Accordingly, a variety of sources, targets, address types, computation types, and control components are defined for a given core.

Sources for vector-vector unit 610 include Vector Matrix Multiply (VMM) unit 609, activation memory 605, constants from parameter memory 608, partial sum memory 611, partial sum results from prior cycles (TGT partial sums); and partial sum network 603.

Targets for vector-vector unit 610 include partial sum memory 611, partial sum results for subsequent cycles (SRC partial sums), activation unit 612, and partial sum network 603.

Accordingly, a given instruction may read or write from activation memory 605, read from weight memory 607, or read or write from partial sum memory 611. Compute operations performed by the core include vector matrix multiplication by VMM unit 609, vector (partial sum) operations by vector unit 610, and activation functions by activation unit 612.

Control operations include program counters and loop and/or sequence counters.

Thus, memory operations are issued to read weights from addresses in weight memory, read parameters from addresses in parameter memory, read activations from addresses in activation memory, and read/write partial sums to addresses in partial sum memory. Computation operations are issued to perform vector-matrix multiplication, vector-vector operations, and activation functions. Communication operations are issued to select the vector-vector operands, route messages on the partial sum network, and select partial sum targets. Loops over layer outputs and loops over layer inputs are controlled by control operations specifying program counters, loop counters, and sequence counters.

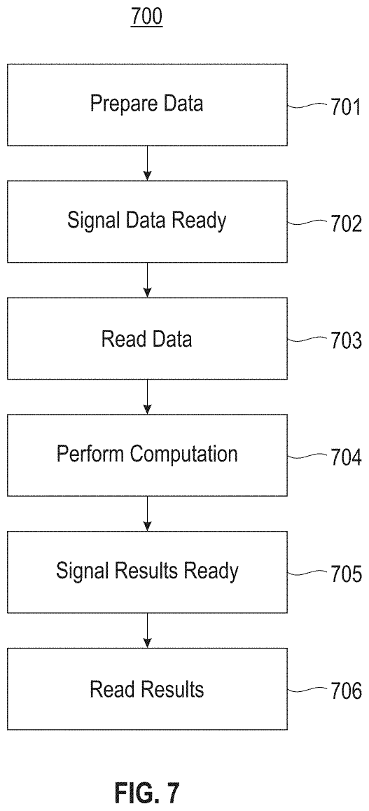

In various embodiments, a memory mapped architecture is implemented that enables an IPU such as described above to communicate with a host by means of memory reads and writes. Referring to FIG. 7, an exemplary method of integration between a host system and an IPU is illustrated. At 701, a host prepares data for inference. At 702, the host informs the IPU that it the data is ready. At 703, the IPU reads the data. At 704, the IPU performs computation on the data. At 705, the IPU informs the host that the results of computation are ready. At 706, the host reads the results.

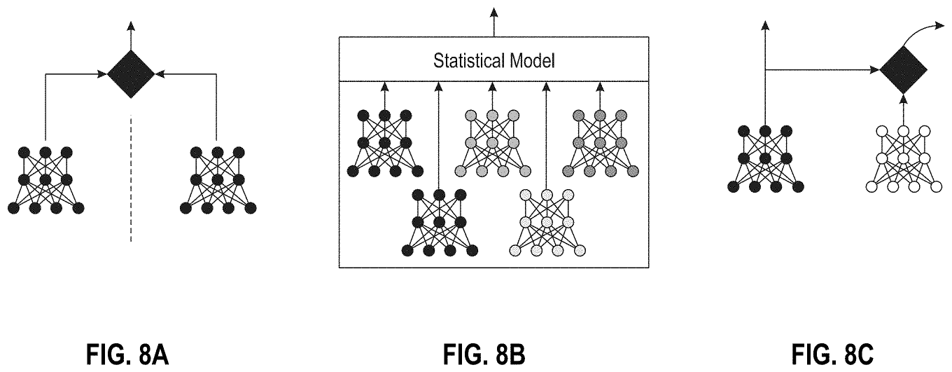

Referring to FIGS. 8A-C, exemplary methods of redundancy are illustrated. It will be appreciated that neuromorphic systems such as those described herein can process data from multiple sensors simultaneously. Multiple networks can reside and be exercised simultaneously. As set out herein, in various embodiments, network results are provided using a high-speed I/O interface.

Referring to FIG. 8A, direct/hardware redundancy is illustrated. In this example, the same model is run more than once and outputs are compared. Referring to FIG. 8B, model redundancy is illustrated. In this example, an ensemble of different data and/or different data is run, and a statistical model (e.g., weighted averaging between models) is applied to arrive at an overall output. Referring to FIG. 8C, apprentice validation is illustrated. In this example, an apprentice model is validated against a control model (or driver).

The low power requirements of architectures described herein allow multiple chips in a system to run redundant networks. Similarly, redundant networks may run on partitions of a chip. In addition, rapid and partial reconfigurability is provided to switch between driving modes and test mode in order to detect/locate/avoid anomalies.

It will be appreciated that inference processing units as set out herein may be integrated into a variety of form-factors. For example, a system-on-chip (SoC) may be provided. A SoC allows scaling to accommodate an area budget. This approach allows on-die integration with consequent fast data transfer capacity. The SoC form factor likewise may be easier and cheaper to package than various alternatives. In another example, a system-in-package (SiP) may be provided. A SiP approach combines the SoC components with IPU dies and supports integration of different process technologies. Minimal implantation changes are required to existing components.

In another example, a PCIe (or other expansion card) is provided. In this approach, an independent development cycle may be imposed for each component. This has the advantage of adopting a standardized high-speed interface and enabling modular integration. This is particularly suitable for early prototypes and datacenters. Similarly, am electronic control unit (ECU) may be provided. This conforms to automotive standards, including with respect to safety and redundancy. An ECU module is suitable for in-vehicle deployment, but generally requires additional R&D time.

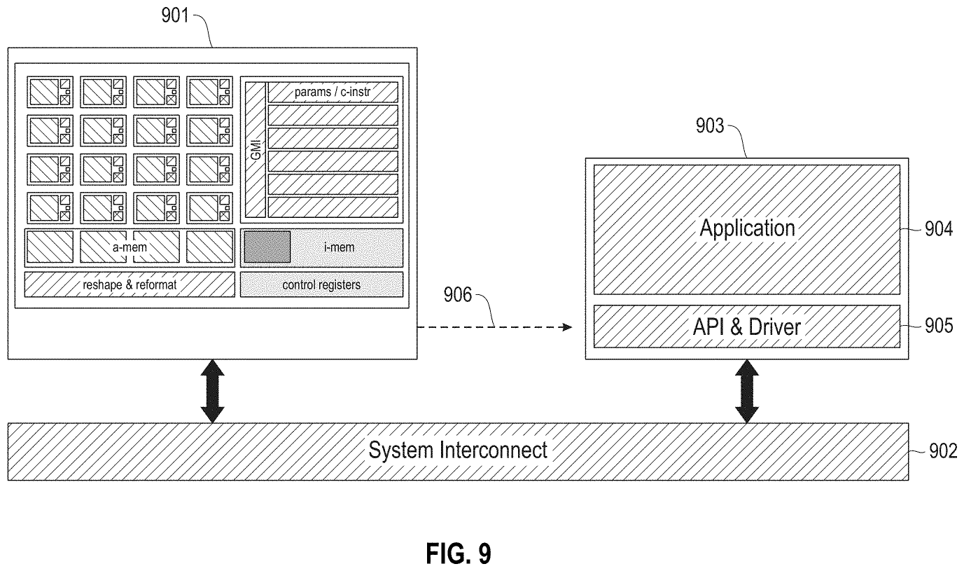

Referring now to FIG. 9, a system architecture of a memory-mapped neural inference engine is illustrated according to embodiments of the present disclosure. Neural inference engine 901 (such as described further above) is connected to system interconnect 902. Host 903 is likewise connected to system interconnect 902.

In various embodiments, system interconnect 902 conforms to an Advanced Microcontroller Bus Architecture (AMBA), such as the a Advanced eXtensible Interface (AXI). In various embodiments, system interconnect 902 is a Peripheral Component Interconnect Express (PCIe) bus or other PCI bus. It will be appreciated that a variety of other bus architectures known in the art are suitable for use as set out herein. In each case, system interconnect 902 connects host 903 to neural inference engine 901 and provides a flat memory-mapped view of the neural inference engine in the virtual memory of the host.

Host 903 includes application 904 and API/driver 905. In various embodiments, the API includes three functions: configure( ), which copies the self-contained neural network program to neural inference engine 901 through the memory map; push( ), which copies the input data to neural inference engine 901 through the memory map, and starts evaluation; and pull( ), which retrieves the output data from neural inference engine 901 through the memory map.

In some embodiments, interrupt 906 is provided by neural inference engine 901, signaling to host 903 that network evaluation has completed.

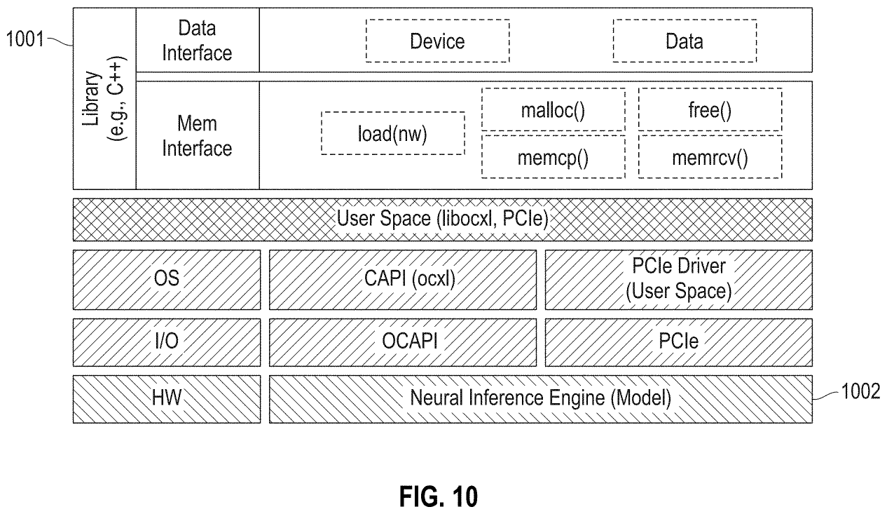

Referring to FIG. 10, an exemplary runtime software stack is illustrated according to various embodiments. In this example, a library 1001 is provided for interfacing with the neural inference engine device 1002. API calls are provided for loading a network, and for memory management (including standard functions for memory allocation and freeing, copying to memory and receiving from memory).

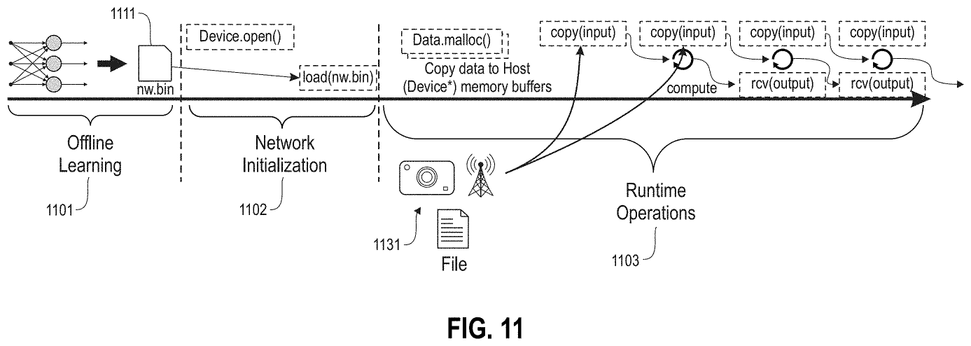

Referring to FIG. 11, an exemplary sequence of execution is illustrated according to embodiments of the present disclosure. In this example, offline learning results in a network definition file, nw.bin 1111. During network initialization 1102, a neural inference device is accessed, for example via the open API call, and network definition file 1111 is loaded. During runtime operation phase 1103, data space is allocated on the neural inference device, and input data 1131 (e.g., image data) is copied to the device memory buffer. One or more computation cycles is performed, as set forth in further detail above. Once a computation cycle is complete output may be received from the device, for example via the rcv API call.

The neural inference device can be memory mapped for inputs and outputs and carries out its computation without host instructions and without requiring external memory for either neural network model or for intermediate activations. This provides a streamlined programming model, in which the neural inference device is simply instructed to compute a neural network, rather than requiring individual instructions for component operations such as matrix multiplication. In particular, there is no translation of convolution into matrix multiplication and so no need for conversion back. There is likewise no need for new calls to be issued for each new layer of the network. As described above with regard to the overall chip design, inter-layer neuron activations never leave the chip. Using this approach, no new network model parameters need be loaded during runtime.

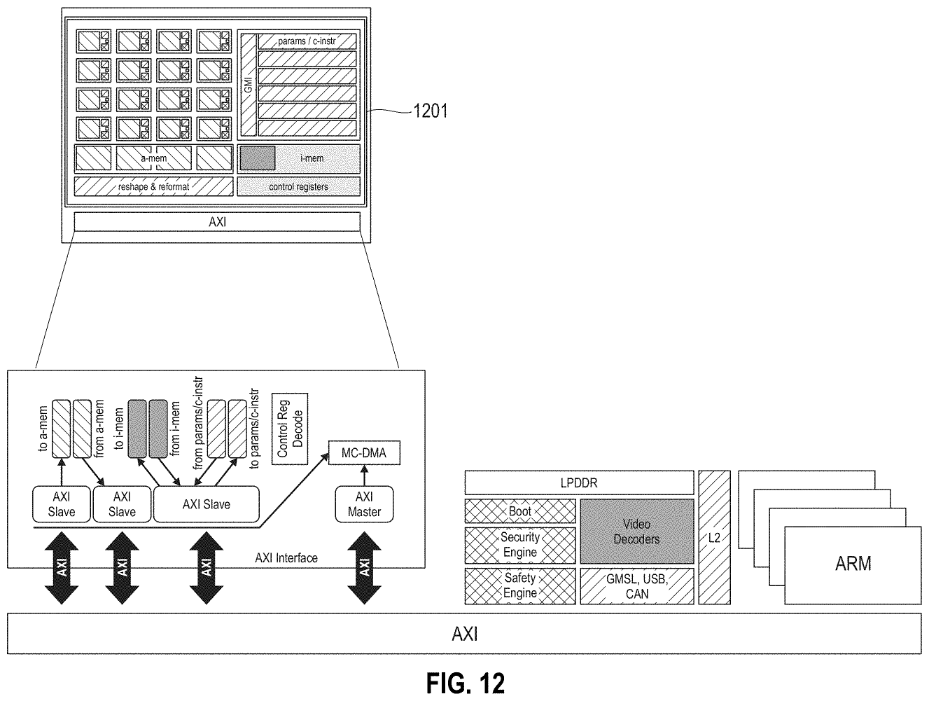

Referring to FIG. 12, an exemplary integration of neural inference device 1201 is illustrated. In this example, the FIFO buffers are provided on the data path, with internal decoding. This provides a multi-channel DMA configuration without the need to have multiple masters. Alternatively, multiple AXI interfaces may be provided with masters, thereby increasing simultaneous throughput.

On the hardware side, a first AXI slave provides a FIFO interface to activation memory of the neural inference device. A second AXI slave provides a FIFO interface from activation memory of the neural inference device. A third AXI slave provides four FIFO interfaces, one to instruction memory, one from instruction memory, one to parameters/control registers, and one from parameter/control registers.

The AXI master initiates data movement to from the neural inference data paths, instructed via MC-DMA. A Multi-Channel DMA Controller (MC-DMA) provides a programmable DMA engine that can simultaneously execute data movement for multiple AXI slaves.

Applications built for this integration scenario use API routines for tasks (e.g., sendTensor, recvTensor). The runtime library is accordingly agnostic to specific hardware instances, while the driver is built for a given hardware configuration.

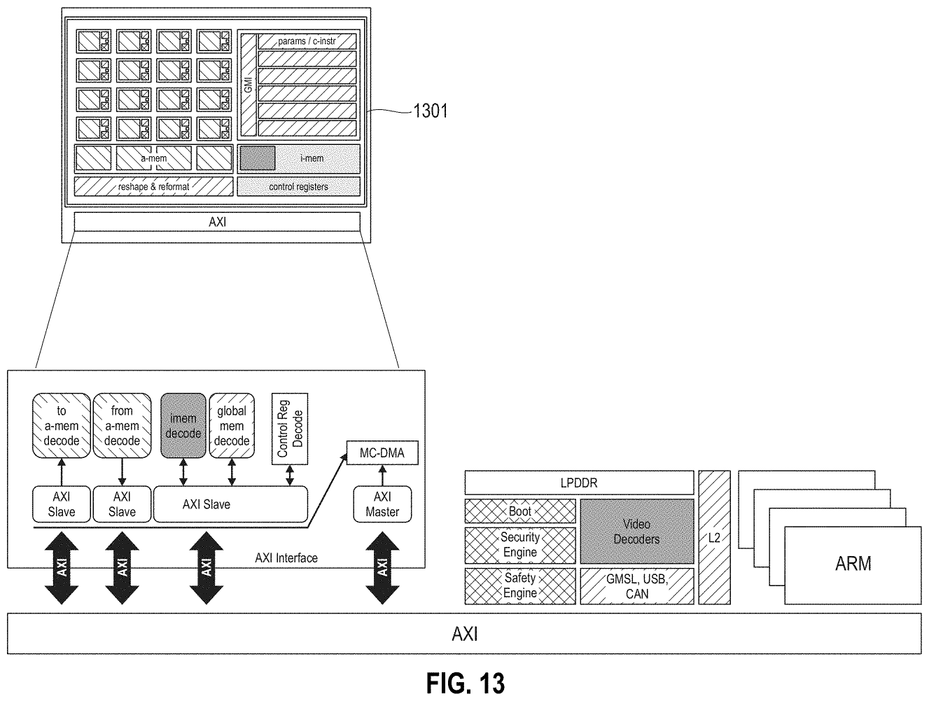

Referring to FIG. 13, an exemplary integration of neural inference device 1301 is illustrated. In this example, a fully memory mapped interface is used.

On the hardware side, a first AXI slave provides a memory mapped interface to activation memory of the neural inference device. A second AXI slave provides a memory mapped interface from activation memory of the neural inference device. A third AXI slave provides memory mapped interfaces, one for instruction memory, one for global memory, and one for parameters/control registers.

The AXI master initiates data movement to from the neural inference data paths, instructed via MC-DMA. A Multi-Channel DMA Controller (MC-DMA) provides a programmable DMA engine that can simultaneously execute data movement for multiple AXI slaves.

Applications built for this integration scenario use API routines for tasks (e.g., sendTensor, recvTensor). The runtime library is accordingly agnostic to specific hardware instances, while the driver is built for a given hardware configuration.

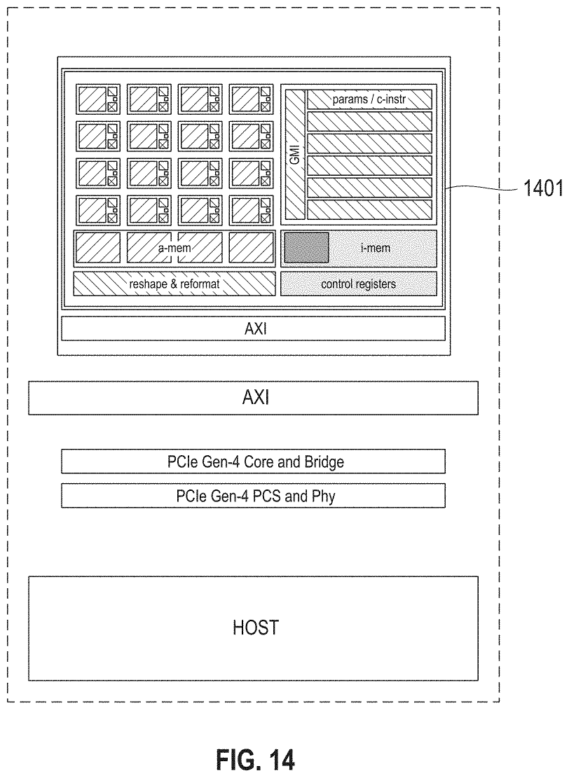

Referring to FIG. 14, an exemplary configuration is illustrated in which neural inference device 1401 is interconnected to a host via a PCIe bridge.

In some embodiments, a runtime is provided in the application layer. In such embodiments, the application exposes the primary interface (e.g., Configure, Put Tensor, Get Tensor) to other applications. A basic software layer communicates with the neural inference device via a PCIe Driver, creating the abstraction layer. The neural inference device is then connected to the system via a high-speed interface as a peripheral device.

In some embodiments, a runtime driver is provided that exposes the primary interface (e.g., Configure, Put Tensor, Get Tensor) to other AUTOSAR applications. The neural inference device is then connected to the system via a high-speed interface as a peripheral device.

The techniques and layout described above enable a variety of multiple neural inference device models. In some embodiments, multiple neural inference modules communicate with a host over a chosen high-speed interface. In some embodiments, multiple neural inference chips communicate with each other and host over a high-speed interface with a possibility of using glue logic. In some embodiments, multiple neural inference dies communicate over a dedicated interface to either a host or other neural inference dies with a possibility of using glue logic (on chip or over an interposer). In some embodiments, multiple neural inference systems-in-package communicate with each other and/or a host on-die over a high-speed interface. Exemplary interfaces include PCIe gen4/5, AXI4, SerDes, and custom interfaces.

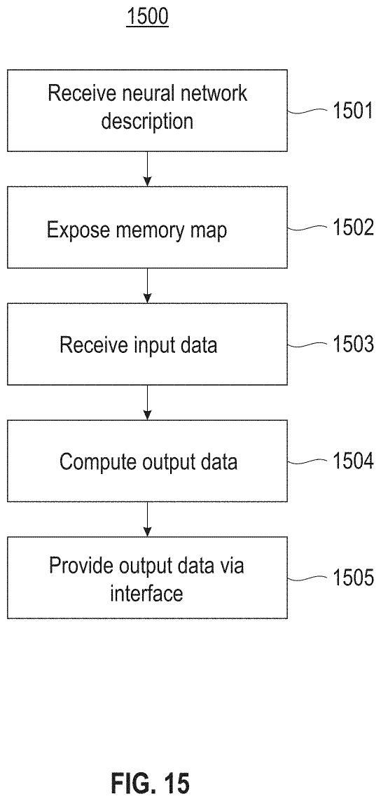

Referring to FIG. 15, a method 1500 for receiving 1501 a neural network description at a neural network processor system via an interface from a host, the neural network processor system comprising at least one neural network processing core, an activation memory, an instruction memory, and at least one control register, the neural network processing core adapted to implement neural network computation, control and communication primitives, the interface operatively connected to the neural network processor system. The method also includes 1502 exposing a memory map via the interface, the memory map comprising regions corresponding to each of the activation memory, instruction memory, and at least one control register. The method also includes 1503 receiving input data at the neural network processor system via the interface. The method also includes 1504 computing output data from the input data based on the neural network model. The method also includes 1505 providing the output data from the neural network processor system via the interface. In some embodiments, the method includes 1506 receiving a neural network description via the interface, receives input data via the interface, and provides output data via the interface.

As set out above, in various embodiments, a memory-mapped neural inference engine is provided, comprising one or more neural inference chips with peripheral communication interfaces to communicate to hosts, sensors, and/or other inference engines. In some embodiments, each neural inference chip is memory-mapped and uses a reduced set of communication API primitives, such as: configure_network( ), push_data( ), pull_data( ). In some embodiments, interchangeable interfaces are used to communicate with the neural inference engine, for example: AXI, PCIe, USB, Ethernet, Firewire, or wireless. In some embodiments, multiple levels of hardware, software, and model-level redundancy are used for increased system yield and correct system operation. In some embodiments, firmware is used to manipulate and buffer incoming/outgoing data for improved performance. In some embodiments, a runtime programming model is used to control the neural accelerator chips. In some embodiments, a hardware-firmware-software stack is used to implement a plurality of applications on the neural inference engine.

In some embodiments, the system operates in a stand-alone mode by incorporating on-board non-volatile memory (such as Flash or SD cards) to store the system's configuration and operating parameters, or to resume from a previous state. In some embodiments, the performance of the system and the communication infrastructure supports real-time operation and communication with the neural accelerator chips. In some embodiments, the performance of the system and the communication infrastructure support faster than real-time operation and communication with the neural accelerator chips.

In some embodiments, the neural inference chips, firmware, software, and communication protocols allow multiple such systems to be arrayed into a larger-scale system (a multi-chip system, a multi-board system, a rack, a datacenter, etc.). In some embodiments, the neural inference chips and microprocessor chips make up an energy-efficient, real time-processing hybrid cloud computing system. In some embodiments, the neural inference chips are used in a cloud system for sensor-, neural-, video-, and/or speech-based and modeling applications. In some embodiments, an interface controller is used to communication with other cloud segments/hosts, which may use various communication interfaces.

In some embodiments, firmware and software stacks (including drivers) perform inference engine/microprocessor, inference engine/host, and microprocessor/host interactions. In some embodiments, a runtime API is provided that performs the low-level interactions with the neural inference chips. In some embodiments, a software stack is provided that includes an operating system, and automatically maps and sequences the workload and user applications on to the system's devices.

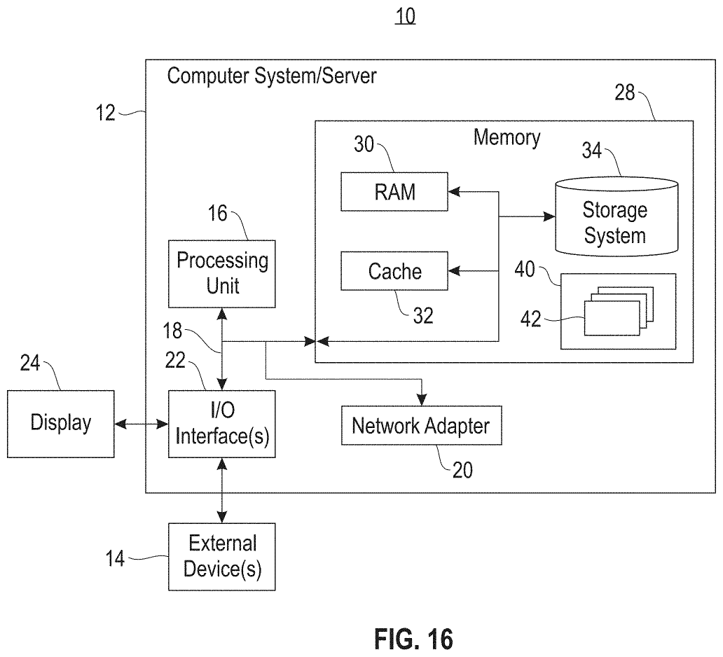

Referring now to FIG. 16, a schematic of an example of a computing node is shown. Computing node 10 is only one example of a suitable computing node and is not intended to suggest any limitation as to the scope of use or functionality of embodiments of the invention described herein. Regardless, computing node 10 is capable of being implemented and/or performing any of the functionality set forth hereinabove.

In computing node 10 there is a computer system/server 12, which is operational with numerous other general purpose or special purpose computing system environments or configurations. Examples of well-known computing systems, environments, and/or configurations that may be suitable for use with computer system/server 12 include, but are not limited to, personal computer systems, server computer systems, thin clients, thick clients, handheld or laptop devices, multiprocessor systems, microprocessor-based systems, set top boxes, programmable consumer electronics, network PCs, minicomputer systems, mainframe computer systems, and distributed cloud computing environments that include any of the above systems or devices, and the like.

Computer system/server 12 may be described in the general context of computer system-executable instructions, such as program modules, being executed by a computer system. Generally, program modules may include routines, programs, objects, components, logic, data structures, and so on that perform particular tasks or implement particular abstract data types. Computer system/server 12 may be practiced in distributed cloud computing environments where tasks are performed by remote processing devices that are linked through a communications network. In a distributed cloud computing environment, program modules may be located in both local and remote computer system storage media including memory storage devices.

As shown in FIG. 16, computer system/server 12 in computing node 10 is shown in the form of a general-purpose computing device. The components of computer system/server 12 may include, but are not limited to, one or more processors or processing units 16, a system memory 28, and a bus 18 that couples various system components including system memory 28 to processor 16.

Bus 18 represents one or more of any of several types of bus structures, including a memory bus or memory controller, a peripheral bus, an accelerated graphics port, and a processor or local bus using any of a variety of bus architectures. By way of example, and not limitation, such architectures include Industry Standard Architecture (ISA) bus, Micro Channel Architecture (MCA) bus, Enhanced ISA (EISA) bus, Video Electronics Standards Association (VESA) local bus, and Peripheral Component Interconnect (PCI) bus.

Computer system/server 12 typically includes a variety of computer system readable media. Such media may be any available media that is accessible by computer system/server 12, and it includes both volatile and non-volatile media, removable and non-removable media.

System memory 28 can include computer system readable media in the form of volatile memory, such as random access memory (RAM) 30 and/or cache memory 32. Computer system/server 12 may further include other removable/non-removable, volatile/non-volatile computer system storage media. By way of example only, storage system 34 can be provided for reading from and writing to a non-removable, non-volatile magnetic media (not shown and typically called a “hard drive”). Although not shown, a magnetic disk drive for reading from and writing to a removable, non-volatile magnetic disk (e.g., a “floppy disk”), and an optical disk drive for reading from or writing to a removable, non-volatile optical disk such as a CD-ROM, DVD-ROM or other optical media can be provided. In such instances, each can be connected to bus 18 by one or more data media interfaces. As will be further depicted and described below, memory 28 may include at least one program product having a set (e.g., at least one) of program modules that are configured to carry out the functions of embodiments of the invention.

Program/utility 40, having a set (at least one) of program modules 42, may be stored in memory 28 by way of example, and not limitation, as well as an operating system, one or more application programs, other program modules, and program data. Each of the operating system, one or more application programs, other program modules, and program data or some combination thereof, may include an implementation of a networking environment. Program modules 42 generally carry out the functions and/or methodologies of embodiments of the invention as described herein.

Computer system/server 12 may also communicate with one or more external devices 14 such as a keyboard, a pointing device, a display 24, etc.; one or more devices that enable a user to interact with computer system/server 12; and/or any devices (e.g., network card, modem, etc.) that enable computer system/server 12 to communicate with one or more other computing devices. Such communication can occur via Input/Output (I/O) interfaces 22. Still yet, computer system/server 12 can communicate with one or more networks such as a local area network (LAN), a general wide area network (WAN), and/or a public network (e.g., the Internet) via network adapter 20. As depicted, network adapter 20 communicates with the other components of computer system/server 12 via bus 18. It should be understood that although not shown, other hardware and/or software components could be used in conjunction with computer system/server 12. Examples, include, but are not limited to: microcode, device drivers, redundant processing units, external disk drive arrays, RAID systems, tape drives, and data archival storage systems, etc.

The present invention may be a system, a method, and/or a computer program product. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A system comprising:
a neural network processor system, comprising
at least one neural network processing core, an activation memory, an instruction memory, and at least one control register, the neural network processing core adapted to implement neural network computation, control and communication primitives;
a memory map comprising regions corresponding to each of the activation memory, instruction memory, and at least one control register,
an interface operatively connected to the neural network processor system,
the interface being adapted to communicate with a host and to expose the memory map.

2. The system of claim 1, wherein the neural network processor is configured to receive a neural network description via the interface, to receive input data via the interface, and to provide output data via the interface.

3. The system of claim 2, wherein the neural network processor system exposes an API via the interface, the API comprising methods for receiving the neural network description via the interface, receiving input data via the interface, and providing output data via the interface.

4. The system of claim 1, wherein the interface comprises an AXI, PCIe, USB, Ethernet, or Firewire interface.

5. The system of claim 1, further comprising a redundant neural network processing core, the redundant neural network processing core configured to compute a neural network model in parallel to the neural network processing core.

6. The system of claim 1, where the neural network processor system is configured to provide redundant computation of a neural network model.

7. The system of claim 1, where the neural network processor system is configured to provide at least one of hardware, software, and model-level redundancy.

8. The system of claim 2, wherein the neural network processor system comprises programmable firmware, the programmable firmware configurable to process the input data and output data.

9. The system of claim 8, wherein said processing comprises buffering.

10. The system of claim 1, wherein the neural network processor system comprises non-volatile memory.

11. The system of claim 10, wherein the neural network processor system is configured to store configuration or operating parameters, or program state.

12. The system of claim 1, wherein the interface is configured for real time or faster than real time operation.

13. The system of claim 1, wherein the interface is communicatively coupled to at least one sensor or camera.

14. A system comprising a plurality of the systems of claim 1, interconnected by a network.

15. A system comprising a plurality of the systems according to claim 1 and a plurality of computing nodes, interconnected by a network.

16. The system of claim 15, further comprising a plurality of disjoint memory maps, each corresponding to one of the plurality of the systems according to claim 1.

17. A method comprising:
receiving a neural network description at a neural network processor system via an interface from a host,
the neural network processor system comprising at least one neural network processing core, an activation memory, an instruction memory, and at least one control register, the neural network processing core adapted to implement neural network computation, control and communication primitives,
the interface operatively connected to the neural network processor system;
exposing a memory map via the interface, the memory map comprising regions corresponding to each of the activation memory, instruction memory, and at least one control register;
receiving input data at the neural network processor system via the interface;
computing output data from the input data based on the neural network model;
providing the output data from the neural network processor system via the interface.

18. The method of claim 17, wherein the neural network processor system receives a neural network description via the interface, receives input data via the interface, and provides output data via the interface.

19. The method of claim 17, wherein the neural network processor system exposes an API via the interface, the API comprising methods for receiving the neural network description via the interface, receiving input data via the interface, and providing output data via the interface.

20. The method of claim 17, wherein the interface operates at real time or faster than real time speed.
